(19) United States
(12) Patent Application Publication
(10) Pub. No.: US 2011/0254762 A1
(43) Pub. Date: Oct. 20, 2011

(54) MACHINE INTERFACES

(75) Inventors: Tobias Dahl, Oslo (NO); David Vågenes, Oslo (NO); Matthew Tuttle, Oslo (NO); Bjørn Cato Syversurd, Oslo (NO)

(73) Assignee: Elliptic Laboratories AS, Oslo (NO)

(21) Appl. No.: 13/062,504

(22) PCT Filed: Sep. 7, 2009
(86) PCT No.: PCT/GB2009/002145

§ 371 Date: Jun. 30, 2011

(30) Foreign Application Priority Data
Sep. 5, 2008 (GB) 0816222.4

(51) Int. Cl. G09G 5/00; H03K 17/94

(52) U.S. Cl. 345/156; 341/20

(57) ABSTRACT

Apparatus for determining the movement of an object comprises a plurality of ultrasonic transducers 1,4;16 arranged to enable the location of the object to be determined by transmission and reflection of signals between the transducers 1,4;16. A yielding surface 2;12 is arranged in proximity to the transducers such that movement of the object into the surface upon application of a yielding pressure to the yielding surface 2;12 can be detected.

This invention relates to interfaces for allowing a human to control a machine, particularly although not exclusively a computer.

Many different ways of allowing a human user to interact with a computer to control it have been proposed. While many of these offer various advantages, the keyboard and mouse or touchpad remain almost ubiquitous. One proposal which has been made in the past is to use a so called ‘touchless’ interface in which the movements of a user's finger or hand are tracked and interpreted to carry out functions on the computer such as directing the movement of an on-screen cursor. One potential drawback with such arrangement is that it might be difficult for a user to know exactly where in space to carry out the appropriate movements in order for them to be properly interpreted. This has led to the suggestion of providing some sort of frame or dedicated surface defining a zone of sensitivity in which the user is intended to carry out his or her movements. However, by confining the user's movements to a surface, the interface is effectively reduced to the equivalent of a touchpad and therefore loses many of the benefits of a touchless system.

It is an objective of the present invention to provide an improved interface and when viewed from a first aspect the present invention provides apparatus for determining the movement of an object comprising a plurality of transducers arranged to enable the location of the object to be determined by transmission and reflection of signals between the transducers; and a yielding surface arranged in proximity to the transducers such that movement of the object into the surface upon application of a yielding pressure thereto can be detected.

Thus it will be seen by those skilled in the art that in accordance with the invention rather than a purely touchless system, a yielding surface is provided with which the user can interact in such a way that movement of the object, which could for example be the user's finger, another part of the hand or an inanimate object, can be detected as it presses into the surface and this can be used in various ways to control a machine such as a computer. It will be further appreciated that the degree of control which can be afforded by such an arrangement is, at least in preferred embodiments, greater than that available with say a touchpad or other pressure-sensitive interface since it is the actual physical location of the object which is detected rather than the pressure applied to a pressure pad. This can therefore allow, in some embodiments, a continuous range of detected movement into the surface, whereas in a touchpad typically only the presence or absence of pressure can be detected. There are vast numbers of applications which could benefit from this: for example any application where a user manipulates a virtual ‘3D’ object. However even if a simple ‘on-off’ detection of pressure is employed rather than a quantitative detection, embodiments of the invention can still provide advantages in terms of allowing a dual touch-based and touchless interface as will be explained later.

Another advantage that can be achieved in accordance with the present invention is that a haptic feedback can be given for a control system which would otherwise be ‘touchless’ without sacrificing all of the flexibility of movement offered by such systems. The Applicant believes that this has the potential to provide a very advantageous compromise between the flexibility of a touchless system and the more comfortable “feel” of a touch-based system. The user's sense of the interface can thus be improved, e.g. the method of selecting and dragging and item on screen can actually be felt by dragging a finger across the surface; the working third dimension could increase the interfacing possibilities such as enabling clicking while scrolling, clicking up, clicking down in different directions, etc., and may lead to a reduction in the area required for an effective interface.

The system could be used to determine just locations of the object (e.g. at discrete points in time) or it could be configured to determine dynamic parameters associated with movement of the object such as the speed of movement, force applied to the yielding surface (through deceleration and knowledge e.g. of the modulus of elasticity)

The yielding surface could be reflective to the radiation transmitted by the transducers so that the position of the object pressing on the surface is determined indirectly through the movement of the surface. In a set of preferred embodiments however the yielding surface is at least partially and preferably fully transparent to the radiation employed by the transducers so that the location of the object can be determined directly. Depending upon the nature of the surface, this can allow a more accurate positioning to be carried out, but it also opens up the possibility of detecting the position of the object both above and below the rest position of the surface (that is the position of the surface before a yielding pressure is applied to it by the object). Of course such arrangements give rise to many further possibilities for the types of control that a user might have over a computer or other machine. To give one non-limiting example, movement above this surface might be interpreted using a gesture recognition system to perform specific tasks associated with specific gestures (e.g. open file, save file, minimise window, cycle windows, etc.) whereas movement along the surface when a yielding pressure is applied thereto could be interpreted to direct the movement of a cursor on-screen.

As mentioned previously the ability of certain embodiments of the invention to allow a dual touch-based and touchless interface is of significant advantage even if a simple ‘on-off’ detection of pressure is employed rather than a quantitative detection (although quantitative detection is not excluded).

The transducers could employ any suitable radiation for detecting the location of the object. For example, they might comprise transmitters and receivers of electromagnetic waves such as microwaves, infrared or visible light. In presently preferred embodiments however, the transducers are arranged to transmit and receive sonic radiation, preferably ultrasonic radiation: that is sound waves having a base frequency greater than 20 kHz, preferably in the range 40 to 120 kHz, more preferably in the range 60 to 100 kHz, most preferably 70 to 90 kHz. Ultrasonic location has several advantages including the availability of relatively inexpensive components and the relative lack of naturally or artificially occurring interference/noise at the relevant frequencies. It is also envisaged that mixed transducers could be employed—e.g. optical and sonic.

In one set of embodiments envisaged optical transducers are used with a surface which is at least partially reflective. For example a light source could be used to project a pattern of lights such as a speckle pattern onto the surface, with light sensors arranged to detect changes in the pattern corresponding to a yielding pressure being applied to the surface.

The transducers could be used to determine the location of the object by a simple time-of-flight triangulation calculation, but preferably a channel impulse response is calculated and the impulse responses used to determine an impulse response pattern which is characteristic of the object to be located. More detail on the calculation and interpretation of channel impulse responses is given in our co-pending application WO 2006/067436. Of course, it is likely that there will be several interfering reflections from parts of the structure around the yielding surface that will give rise to reflected signals which could potentially obscure the signals reflected from the object. However, these can be easily accounted for, e.g. by subtracting the reflections from known objects within the transducers' field of view. For example, where impulse responses are employed, an initialisation procedure could be used whereby a base-line impulse response is measured e.g. upon setting up of a system, or whenever it is powered on, or periodically, or on demand; and the baseline impulse response subtracted from the impulse responses subsequently measured.

Preferably at least three receiving transducers are employed. Only a single transmitter is necessary although it may be advantageous in some embodiments to employ a plurality. Of course, the larger the number of transmitters and receivers used, the greater will be the resolution, which might for example provide multi-touch functionality, whereby separate objects can be detected simultaneously.

The transducers may be arranged in any suitable arrangement. In one set of embodiments a or the transmitter is located centrally with respect to the yielding surface or a designated active region thereof. In some embodiments the transducers are mounted on a common plane, preferably parallel to the initial position of the yielding surface. In some preferred embodiments an array of transducer elements is provided: for example, a rectangular array. The elements could each work as a receiver and a transmitter, or individual elements could be designated either for transmission or reception. Alternatively, multiple layers of elements, including at least one transmitter and at least one receiver layer could be used. The elements could be single elements placed closely together, or they could comprise a common substrate subdivided into transmitting and receiving elements. A material well suited for this purpose which is well known in the art would be a PVDF (polyvinylidene difluoride) foil. The foil could either be made to vibrate along its depth dimension, or the individual elements could be folded slightly so that they vibrate normally to their curvature when voltage is applied to them. In another set of embodiments the elements could be provided by a capacitive micro-machined ultrasonic transducer (CMUT) of the type known per se in the art.

The yielding surface could be separated from the transducers by an air or other fluid gap. The yielding surface in such embodiments could be self-supporting, or preferably supported by a frame—e.g. to form a box.

In other embodiments a material medium could be provided between the yielding surface and the transducers. Clearly in such embodiments the medium would also need to be yielding. Preferably it is of reticulated structure—e.g. an elastomeric foam. The material medium could be a discrete layer between the yielding surface and the transducers or it could, for example, itself provide the yielding surface. Thus to take a preferred example, the material medium could comprise a foam layer, the outermost surface of which provides the yielding surface. In some preferred embodiments the apparatus comprising the yielding surface and the transducers is flexible—e.g. to allow it to be folded or rolled. This could be particularly convenient for mobile human-computer interfaces—e.g. for use with a laptop computer.

The yielding surface could be of a material and/or construction such as to give it a temporary or permanent memory. For example, such a surface could be used by a user to emulate a moulding or shaping process. The surface might return to its original shape either over time or upon an external restoring influence, the nature of which would depend upon the nature of the surface but might, for example, be a physical restoring force, an applied vibration, heat, light or the application of an electrical current. In one set of preferred embodiments, the surface is elastic so that upon removal of the yielding pressure it returns to its initial configuration.

In some embodiments separate means could be provided for determining that the surface had been touched—e.g. vibration or pressure sensors which might be used for example to initiate tracking of the object touching the surface. For example, when such pressure were detected, this could be used to “switch on” control by the object.

A single surface might be provided, but equally a plurality of discrete surfaces might be used in some embodiments. These could be co-planar, parallel but at different heights, or non-parallel: e.g. a box or any other shape with multiple ‘touch’ sides. It could comprise such multiple non-connected surfaces which can be touched independently but which may be linked in terms of interaction options. Multiple surfaces could, for example, allow a separate surface for each hand, or to give separate surfaces for control of separate functions or programs. Of course, a single surface could be subdivided into different areas, e.g. by suitable markings, variation in texture, thickness, colour, etc.

In one set of envisaged embodiments, light could be projected onto or generated by the surface in order to give changeable indications. Such indications might correspond to different functionality, the provision of information, feedback for the user or any other purpose. More generally the surface could comprise a flexible screen for displaying graphics, information, text etc. i.e. a touch screen. It is envisaged that this could be combined with the embodiments mentioned earlier whereby a reflected light pattern is used to detect yielding of the surface.

The surface is planar in presently envisaged embodiments but it could be non-planar—e.g. it could be arranged into another form or shape such as a ball, hemisphere, hyperbola etc.

Additionally or alternatively, physical movement could be imparted to the surface either to give feedback to a user or to provide additional functionality. In one example the surface could be made to vibrate either continuously or at desired times of course such vibration could be varied in terms of its frequency, amplitude, wave form, etc., to give additional information.

In another envisaged example the surface could be made to bend or slope—e.g. by appropriate manipulation of a supporting frame or material medium—which might give the user an enhanced experience depending upon the particular type of control being carried out. It is envisaged that this could have particular benefit in applications where the surface is used as part of the controls for a gaming application.

In yet another example, the height of the surface might be variable depending upon user input, the status of machine or program being controlled or indeed for any other reason. A yet further example would be to alter the tension or texture of the surface.

In many applications, a single yielding surface layer will provide the desired functionality. However, it is envisaged in a further set of embodiments that a multilayered surface could be provided. Preferably the layers are separated from one another either by a gap or by an intermediate material. Such an arrangement would allow a user to “push through” the uppermost layer to apply pressure to a lower layer. This would give the user a different feel and again, there are many and varied possibilities for exploiting this to give an enhanced user experience. In one example it might be used to allow the user to access additional, perhaps more advanced, functions or to carry out a faster or slower movement in response to the user's movement along the surface or perhaps to alter the sensitivity with which the user's movement is interpreted. Of course, more than two layers could be provided and the number of layers could vary across a surface.

It will be appreciated by those skilled in the art that the principles set forth hereinabove open up a very large number of possibilities for enhancing interaction and control between a human user and a computer or other machine, some of which have been mentioned already. But to give just a few further non-limiting examples, the surface described in accordance with the invention could be used to provide a virtual keyboard for controlling a computer at a much lower cost and with no mechanically engaging parts and also with the flexibility say to change the keyboard into a “mouse pad”. In another example, the surface could be used as a three-dimensional mouse, taking advantage in accordance with some preferred embodiments of the invention of being able to track to object both on and above the surface and, by the application of variable pressure, at a variable depth below the initial position of the surface.

Another possible application would be in the medical field either for treatment of a patient or for training purposes, whereby the surface might for example be used to emulate part of a body and/or where the surface or a cover thereof could be disposable for hygiene purposes. Generally, the surface could be disposable or interchangeable for hygiene purposes or to use surfaces with different markings for different applications.

When viewed from a further aspect the invention provides use of a yieldable surface to control a computer in accordance with the amount of pressure applied to the surface. More generally, the surface could be used to determine the presence or absence of pressure (the object's location being used to determine where on the surface the pressure is applied) or, as in preferred embodiments, the amount of pressure and therefore degree of yielding of the surface is detected.

Although the invention has thus far been described using the example of a human finger as the object detected, this is not essential. Any other part of the human body or any suitable inanimate object could be used. Indeed the resolution of the ‘imaging’ system (which could be optical, ultrasonic, microwave etc.) could allow a distinction to be made between the nature of different objects which could then allow different functions to be employed: e.g. different functions for a thumb vs. a finger; or a pen for writing, finger for clicking, brush for producing brush-strokes etc.

Clearly the size of the surface will be dependent upon the application: one size could be small enough only to be operated using small finger movements; whereas another could be large enough that the user could perfot in large movements using both hands.

An embodiment of the invention will now be described, by way of example only, with reference to the accompanying drawings in which:

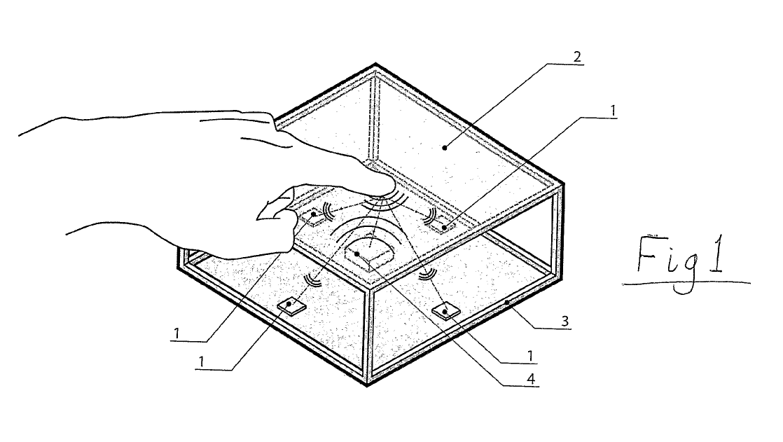

FIG. 1 is a schematic diagram of a first embodiment of the invention; and

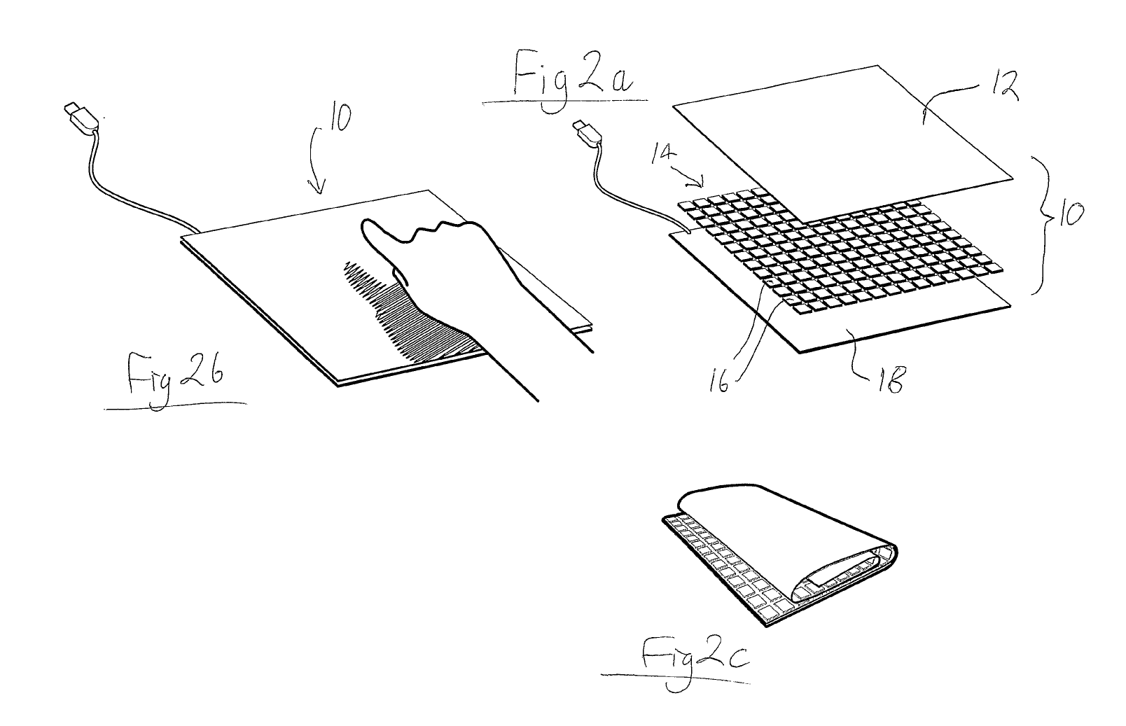

FIGS. 2a to 2c show various schematic views of a second embodiment of the invention

FIG. 1 shows an apparatus in accordance with the invention. It comprises a frame 3 supporting a flexible elastic surface 2 stretched across its upper face. The cover could be made of any suitable material—e.g. Acoustex (trade mark) available from Acoustex Fabrics of Burlington, Mass. Mounted to the centre of the base of the frame is an ultrasonic transmitter 4 such as a piezo-electric element. Four corresponding microphones 1 for receiving reflected ultrasonic radiation are arranged on the four sides of the base of the frame 3. Control electronics and connections to a computer are not shown but are easily within the capability of someone skilled in the art. Connection to a computer could, for example, be by means of a standard USB, Bluetooth, infra-red, or Zigbee or any other suitable connection.

In use the user presses his or her finger against the surface 4 to cause it to yield and elastically deform. The ultrasonic transmitter 4 transmits either a periodic series of bursts or a continuous signal which passes through the yielding surface 2 and is reflected from the finger. The reflected signal is received by the four receivers 1. The transmitted and received signals are then used to calculate a channel impulse response for each receiver 1 in the manner known per se in the art—e.g. from WO 2006/067436. These are combined to calculate the position of the finger. Of course the impulse responses will include echoes from the frame etc. but these can be subtracted or otherwise accounted for since they will generally be constant or at least identifiable.

The position of the finger can be tracked over time—e.g. for use in a cursor control application. Alternatively the discrete positions of the finger can be used—e.g. in a keyboard emulator. It will be appreciated however that the five transducers (one transmitter and four receivers) can easily give an accurate three-dimensional location of the finger, especially the fingertip. This can therefore be used to determine how far the user is pressing his/her finger into the surface 2 which allows a quantitative third dimension of control. Moreover location and shape recognition can be carried out on the hand even if it is not in touch with the surface 2 given its transparency to ultrasound. This allows a smooth transition between a truly touchless interface and one based on a yielding surface, thereby further enhancing the range of functionality available.

A second embodiment of the invention is shown in FIGS. 2a to 2c. In this embodiment the interface apparatus is in the form of a flexible mat 10 which can be rolled or folded as demonstrated in FIG. 2c. FIG. 2a shows an exploded view of the layers which make up the mat. The uppermost layer 12 provides the yielding surface and can, for example, be made of Acoustex as previously mentioned, although many other materials could be used instead. Beneath the surface layer is a transducer layer 14 which comprises an array of ultrasonic transducer elements 16 which can be fabricated as a single sheet. In this example each transducer is configured both to transmit and receive ultrasonic signals, although dedicated transmitters and receivers could equally be used. At the base of the mat is a substrate layer 18 which provides electrical connections to the transducers, possibly some processing functionality, and has a standard USB connection 20 for a computer.

The second embodiment operates in a similar manner to the first in that the transducers 16 send and receive ultrasonic signals which pass through the upper layer 12 and are reflected by the finger or hand. By analysis of the echoes the position of a finger or hand can be detected either when touching the surface 12 or when above it as shown in FIG. 2b. The large number of transducers provides a high resolution positioning and/or reliable gesture recognition in touchless mode. In this embodiment the transducers do not necessarily need to measure deformation of the upper surface 12 quantitatively—indeed given the relative thinness of the mat 10 as a whole, deformation of the layer normal to its surface is relatively small.

The embodiments described above are just two simple examples and there are many other ways of implementing the invention. For example the invention could be used for 3D moulding and modelling: a user could mould shapes in 3D for design by using x and y movements to rotate the object, and the z dimension to mould. This could be done on large embodiments of the invention or small ones. It could be employed in a 3D medical pad: a version for use with a medical application (or something else) separate from a computer screen. The yielding surface and/or cover thereon could be designed specifically for medical purposes and could also be made disposable. A small and simple embodiment of the invention could be used as a joystick or gamepad. An embodiment of the invention could be built into clothes/accessories—e.g. incorporated into a jacket or trousers, or a bag to provide the user with multiple touchpad functionalities. It might also be used for rehabilitation training to help people with neurological disabilities such as stroke patients re-learn coordination.

1. Apparatus for determining the movement of an object comprising a plurality of transducers arranged to enable the location of the object to be determined by transmission and reflection of signals between the transducers; and a yielding surface arranged in proximity to the transducers such that movement of the object into the surface upon application of a yielding pressure thereto can be detected.

2. The apparatus of claim 1 wherein the yielding surface is at least partially transparent to the radiation employed by the transducers.

3. The apparatus of claim 1 wherein the transducers are arranged to transmit and receive ultrasonic radiation.

4. The apparatus of claim 1 wherein the yielding surface is at least partially reflective and the transducers comprise: at least one light source arranged to project a pattern of lights onto the yielding surface; and at least one light sensor arranged to detect changes in the pattern corresponding to a yielding pressure being applied to the surface.

5. The apparatus of claim 1 comprising logic configured to calculate channel impulse responses and to use the impulse responses to determine an impulse response pattern which is characteristic of the object to be located.

6. The apparatus of claim 1 comprising at least three receiving transducers.

7. The apparatus of claim 1 comprising a or the transmitter located centrally with respect to the yielding surface or a designated active region thereof.

8. The apparatus of claim 1 wherein the transducers are mounted on a common plane.

9. The apparatus of claim 8 wherein the common plane is parallel to the initial position of the yielding surface.

10. The apparatus of claim 1 comprising an array of transducer elements.

11. The apparatus of claim 1 wherein the yielding surface is supported by a frame.

12. The apparatus of claim 1 wherein the yielding surface is separated from the transducers by a fluid gap.

13. The apparatus of claim 1 comprising a material medium between the yielding surface and the transducers.

14. The apparatus of claim 1 comprising a foam layer, wherein the outermost surface of the foam layer provides the yielding surface.

15. The apparatus of claim 1, wherein the apparatus is flexible.

16. The apparatus of claim 1 wherein the yielding surface is of a material or construction such as to give it a temporary or permanent shape memory.

17. The apparatus of claim 1 wherein the yielding surface is elastic so that upon removal of the yielding pressure it returns to its initial configuration.

18. The apparatus of claim 1 comprising a separate detector for determining that the yielding surface has been touched.

19. The apparatus of claim 1 configured so that light is projected onto or generated by the yielding surface.

20. The apparatus of claim 1 wherein the yielding surface comprises a flexible display screen.

21. The apparatus of claim 1 comprising an actuator for imparting physical movement to the yielding surface.

22. The apparatus of claim 1 comprising an actuator for making the yielding surface bend or slope.

23. The apparatus of claim 1 comprising an actuator for altering one or more of the height, tension or texture of the yielding surface.

24. The apparatus of claim 1 wherein the yielding surface layer is multilayered surface.

25. The apparatus of claim 24 wherein the layers of the surface are separated from one another either by a gap or by an intermediate material.

26. A method of controlling a computer according to an amount of pressure applied to a yieldable surface.

27. The method of claim 26 comprising detecting the amount of pressure and therefore the degree of yielding of the surface.

28. The apparatus of claim 1, further configured to detect movement of the object when the object is not touching the surface.
